(19) United States
(12) Patent Application Publication
(10) Pub. No.: US 2026/0177901 A1
(43) Pub. Date: Jun. 25, 2026

(54) EUV PHOTOMASK AND MANUFACTURING METHOD THEREOF

(71) Applicant: Taiwan Semiconductor Manufacturing Company, Ltd., Hsinchu (TW)

(72) Inventors: Wen-Chang HSUEH, Hsinchu (TW); Yan-Syun HUANG, Hsinchu (TW); Hsin-Chang LEE, Hsinchu (TW)

(73) Assignee: Taiwan Semiconductor Manufacturing Company, Ltd., Hsinchu (TW)

(21) Appl. No.: 19/202,968

(22) Filed: May 8, 2025

Related U.S. Application Data
(60) Provisional application No. 63/738,657, filed on Dec. 24, 2024.

(51) Int. Cl. G03F 1/24; G03F 1/52; G03F 1/54; G03F 1/80

(52) U.S. Cl. CPC G03F 1/24; G03F 1/52; G03F 1/54; G03F 1/80

(57) ABSTRACT

A method of manufacturing a photomask includes forming a reflective multilayer stack over a substrate and forming a capping layer over the reflective multilayer stack. An absorber layer is formed over the capping layer and a hard mask is formed over the absorber layer. An opening is formed in the hard mask exposing the absorber layer. The absorber layer is etched using the hard mask as an etching mask. The etching the absorber layer includes applying a first etching gas to the absorber layer, turning on a bias power and a source power, turning off the bias power and the source power, applying a second etching gas to the absorber layer, wherein the first etching gas and the second etching gas are different, and turning on the source power without turning on the bias power.

### RELATED APPLICATION

This application claims priority to U.S. Provisional Ser. No. 63/738,657 filed on Dec. 24, 2024, the entire content of which is incorporated herein by reference.

### BACKGROUND

Photolithography operations are one of the key operations in the semiconductor manufacturing process. Photolithography techniques include ultraviolet lithography, deep ultraviolet lithography, and extreme ultraviolet (EUV) lithography. The photomask is an important component in photolithography operations. It is important to fabricate EUV photomasks having a high contrast between a high reflectivity part and a high absorption part.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a schematic view of an EUV lithography system with a laser produced plasma (LPP) EUV radiation source in accordance with some embodiments of the present disclosure.

FIG. 2 shows a schematic diagram of an extreme ultraviolet lithography tool according to an embodiment of the disclosure.

FIGS. 3A, 3B, 3C, 3D, and 3E show EUV photomask blanks according to embodiments of the present disclosure.

FIGS. 4A, 4B, 4C, 4D, 4E, and 4F schematically illustrate a method of fabricating an EUV photomask according to an embodiment of the present disclosure.

FIGS. 5A, 5B, 5C, 5D, and 5E schematically illustrate a method of fabricating an EUV photomask according to an embodiment of the present disclosure.

FIG. 6 shows an etching cycle according to embodiments of the present disclosure.

FIGS. 7A, 7B, and 7C schematically illustrate a method of fabricating an EUV photomask according to an embodiment of the present disclosure.

FIG. 8A shows a cross sectional detailed view of an opening formed in an absorber layer of an EUV photomask according to an embodiment of the disclosure. FIG. 8B shows a cross sectional detailed view of a sidewall of an opening formed in an absorber layer according to an embodiment of the disclosure.

FIGS. 9A, 9B, and 9C show cross sectional detailed views of sidewalls of openings formed in an absorber layer according to embodiments of the disclosure.

FIGS. 10A, 10B, 10C, and 10D schematically illustrate a method of fabricating an EUV photomask according to an embodiment of the present disclosure.

FIG. 11 shows a flow chart of manufacturing an EUV photomask according to embodiments of the present disclosure.

FIG. 12 shows a flow chart of manufacturing an EUV photomask according to embodiments of the present disclosure.

FIG. 13 shows a flow chart of manufacturing an EUV photomask according to embodiments of the present disclosure.

FIG. 14 shows a flow chart of manufacturing a semiconductor device according to embodiments of the present disclosure.

FIG. 15 shows a flow chart of manufacturing a semiconductor device according to embodiments of the present disclosure.

FIGS. 16A, 16B, 16C, and 16D show a sequential manufacturing operation of a method of making a semiconductor device in accordance with embodiments of present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described.

Embodiments of the present disclosure provide a method of manufacturing an EUV photomask. More specifically, the present disclosure provides techniques to improve the profile of the circuit pattern formed in the absorber layer of the EUV photomask.

EUV lithography employs scanners using light in the extreme ultraviolet (EUV) region. The mask is a critical component of an EUV lithography system. Because the optical materials are not transparent to EUV radiation, EUV photomasks are reflective masks. Circuit patterns are formed in an absorber layer disposed over the reflective structure. The absorber has a low EUV reflectivity, for example, less than 3-5%.

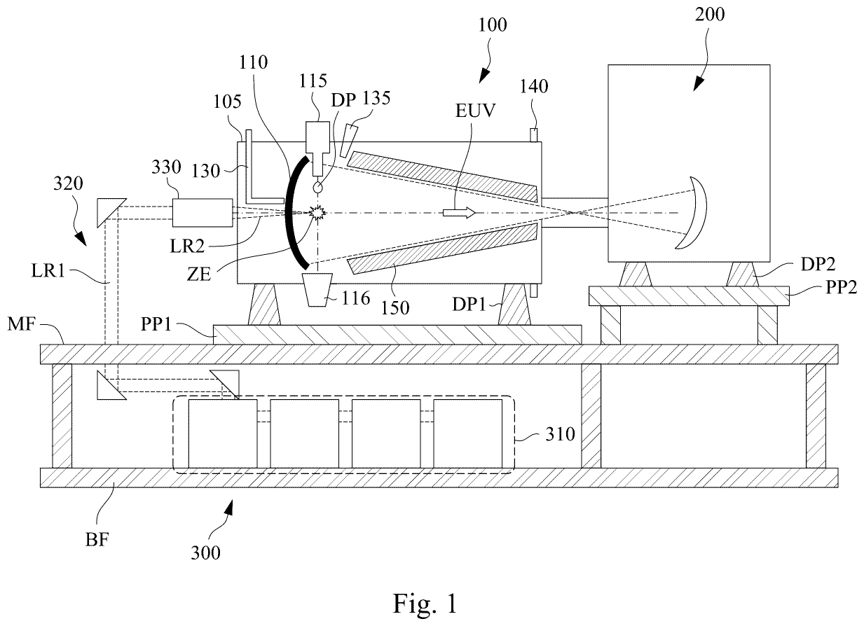

FIG. 1 is a schematic and diagrammatic view of an EUV lithography system. The EUV lithography system includes an EUV radiation source apparatus 100 to generate EUV light, an exposure tool 200, such as a scanner, and an excitation laser source apparatus 300. As shown in FIG. 1, in some embodiments, the EUV radiation source apparatus 100 and the exposure tool 200 are installed on a main floor MF of a clean room, while the excitation laser source apparatus 300 is installed in a base floor BF located under the main floor. Each of the EUV radiation source apparatus 100 and the exposure tool 200 are placed over pedestal plates PP1 and PP2 via dampers DP1 and DP2, respectively. The EUV radiation source apparatus 100 and the exposure tool 200 are coupled to each other by a coupling mechanism, which may include a focusing unit.

The EUV lithography system is designed to expose a resist layer by EUV light (or EUV radiation). The resist layer is a material sensitive to the EUV light. The EUV lithography system employs the EUV radiation source apparatus 100 to generate EUV light, such as EUV light having a wavelength ranging between about 1 nm and about 100 nm. In one particular example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure tool 200 includes various reflective optic components, such as convex/concave/flat mirrors, a mask holding mechanism including a mask stage, and wafer holding mechanism. The EUV radiation EUV generated by the EUV radiation source 100 is guided by the reflective optical components onto a mask secured on the mask stage. In some embodiments, the mask stage includes an electrostatic chuck (e-chuck) to secure the mask. Because gas molecules absorb EUV light, the lithography system for the EUV lithography patterning is maintained in a vacuum or a low pressure environment to avoid EUV intensity loss.

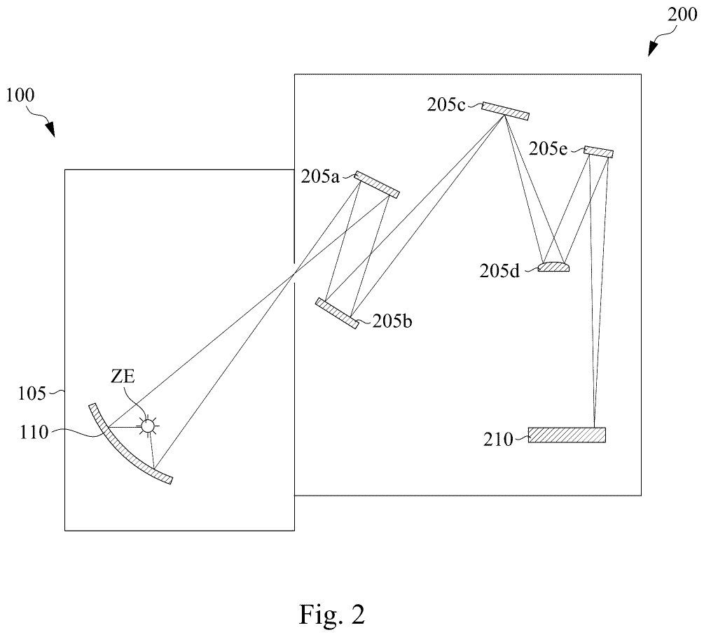

FIG. 2 is a schematic diagram of a detail of an extreme ultraviolet lithography tool according to an embodiment of the disclosure showing the exposure of photoresist coated substrate 210 with a patterned beam of EUV light. The exposure device 200 is an integrated circuit lithography tool such as a stepper, scanner, step and scan system, direct write system, device using a contact and/or proximity mask, etc., provided with one or more optics 205a, 205b, for example, to illuminate a patterning optic 205c, such as a reticle, with a beam of EUV light, to produce a patterned beam, and one or more reduction projection optics 205d, 205e, for projecting the patterned beam onto the substrate 210. A mechanical assembly (not shown) may be provided for generating a controlled relative movement between the substrate 210 and patterning optic 205c. As further shown in FIG. 2, the EUV lithography tool includes an EUV light source 100 including plasma at ZE emitting EUV light in a chamber 105 that is collected and reflected by a collector 110 along a path into the exposure device 200 to irradiate the substrate 210.

As used herein, the term “optic” is meant to be broadly construed to include, and not necessarily be limited to, one or more components which reflect and/or transmit and/or operate on incident light, and includes, but is not limited to, one or more lenses, windows, filters, wedges, prisms, grisms, gratings, transmission fibers, etalons, diffusers, homogenizers, detectors and other instrument components, apertures, axicons and mirrors including multi-layer mirrors, near-normal incidence mirrors, grazing incidence mirrors, specular reflectors, diffuse reflectors and combinations thereof. Moreover, unless otherwise specified, the term “optic,” as used herein, is not meant to be limited to components which operate solely within one or more specific wavelength range(s) such as at the EUV output light wavelength, the irradiation laser wavelength, a wavelength suitable for metrology or any other specific wavelength.

In the present disclosure, the terms mask, photomask, and reticle are used interchangeably. In the present embodiment, the mask is a reflective mask. One exemplary structure of the mask includes a substrate with a suitable material, such as a low thermal expansion material or fused quartz. In various examples, the material includes TiO₂ doped SiO₂, or other suitable materials with low thermal expansion. The mask includes multiple reflective layers deposited on the substrate. The multiple layers include a plurality of film pairs, such as molybdenum-silicon (Mo/Si) film pairs (e.g., a layer of molybdenum above or below a layer of silicon in each film pair). Alternatively, the multiple layers may include molybdenum-beryllium (Mo/Be) film pairs, or other suitable materials that are configurable to highly reflect the EUV light. The mask may further include a capping layer, such as ruthenium (Ru), disposed on the ML for protection. The mask further includes an absorber layer, such as a chromium nitride (CrN) or tantalum boron nitride (TaBN) layer, deposited over the multiple layers. The absorber layer is patterned to define a layer of an integrated circuit (IC). Alternatively, another reflective layer may be deposited over the multiple layers and is patterned to define a layer of an integrated circuit, thereby forming an EUV phase shift mask.

In the present embodiments, the semiconductor substrate is a semiconductor wafer, such as a silicon wafer or other type of wafer to be patterned. The semiconductor substrate is coated with a resist layer sensitive to the EUV light in the present disclosure. Various components including those described above are integrated together and are operable to perform lithography exposing processes. The lithography system may further include other modules or be integrated with (or be coupled with) other modules.

As shown in FIG. 1, the EUV radiation source 100 includes a target droplet generator 115 and a LPP collector 110, enclosed by a chamber 105. The target droplet generator 115 generates a plurality of target droplets DP. In some embodiments, the target droplets DP are tin (Sn) droplets. In some embodiments, the tin droplets each have a diameter about 30 microns (μm). In some embodiments, the tin droplets DP are generated at a rate about 50-50,000 droplets per second and are introduced into a zone of excitation ZE at a speed about 70 meters per second (m/s). Other materials can also be used for the target droplets, for example, a tin containing liquid material such as eutectic alloy containing tin or lithium (Li).

The excitation laser LR2 generated by the excitation laser source apparatus 300 is a pulse laser. In some embodiments, the excitation laser includes a pre-heat laser and a main laser. The pre-heat laser pulse is used to heat (or pre-heat) the target droplet to create a low-density target in a pancake shape, which is subsequently heated (or reheated) by the main laser pulse, generating increased emission of EUV light. In various embodiments, the pre-heat laser pulses have a spot size about 100 μm or less, and the main laser pulses have a spot size about 200-300 μm.

The laser pulses LR2 are generated by the excitation laser source 300. The laser source 300 may include a laser generator 310, laser guide optics 320 and a focusing apparatus 330. In some embodiments, the laser source 310 includes a carbon dioxide (CO₂) or a neodymium-doped yttrium aluminum garnet (Nd:YAG) laser source. The laser light LR1 generated by the laser generator 300 is guided by the laser guide optics 320 and focused into the excitation laser LR2 by the focusing apparatus 330, and then introduced into the EUV radiation source 100.

The laser light LR2 is directed through windows (or lenses) into the zone of excitation ZE. The windows adopt a suitable material substantially transparent to the laser beams. The generation of the pulse lasers is synchronized with the generation of the target droplets. As the target droplets move through the excitation zone, the pre-pulses heat the target droplets and transform them into low-density target in a pancake shape. A delay between the pre-pulse and the main pulse is controlled to allow the target in the pancake shape to form and to expand to an optimal size and geometry. When the main pulse heats the target in a pancake shape, a high-temperature plasma is generated. The plasma emits EUV radiation EUV, which is collected by the collector mirror 110. The collector 110 has a reflection surface that reflects and focuses the EUV radiation for the lithography exposing processes. In some embodiments, a droplet catcher 116 is installed opposite the target droplet generator 115. The droplet catcher 116 is used for catching excess target droplets. For example, some target droplets may be purposely missed by the laser pulses.

The collector 110 includes a proper coating material and shape to function as a mirror for EUV collection, reflection, and focusing. In some embodiments, the collector 110 is designed to have an ellipsoidal geometry. In some embodiments, the coating material of the collector 100 is similar to the reflective multilayer of the EUV mask. In some examples, the coating material of the collector 110 includes multiple layers (such as a plurality of Mo/Si film pairs) and may further include a capping layer (such as Ru) coated on the multiple layers to substantially reflect the EUV light. In some embodiments, the collector 110 further includes a grating structure designed to effectively scatter the laser beam directed onto the collector 110. For example, a silicon nitride layer is coated on the collector 110 and is patterned to have a grating pattern in some embodiments.

In such an EUV radiation source apparatus, the plasma caused by the laser application creates physical debris, such as ions, gases and atoms of the droplet, as well as the desired EUV radiation. It is necessary to prevent the accumulation of material on the collector 110 and also to prevent physical debris exiting the chamber 105 and entering the exposure tool 200.

As shown in FIG. 1, in some embodiments, a buffer gas is supplied from a first buffer gas supply 130 through the aperture in collector 110 by which the pulse laser is delivered to the tin droplets. In some embodiments, the buffer gas is H₂, He, Ar, N₂, or another inert gas. In certain embodiments, H₂ is used as H radicals generated by ionization of the buffer gas can be used for cleaning purposes. The buffer gas can also be provided through one or more second buffer gas supplies 135 toward the collector 110 and/or around the edges of the collector 110. Further, the chamber 105 includes one or more gas outlets 140 so that the buffer gas is exhausted outside the chamber 105. Hydrogen gas has low absorption of the EUV radiation. Hydrogen gas reaching the coating surface of the collector 110 reacts chemically with a metal of the droplet forming a hydride, e.g., metal hydride. When tin (Sn) is used as the droplet, stannane (SnH₄), which is a gaseous byproduct of the EUV generation process, is formed. The gaseous SnH₄ is then pumped out through the outlet 140. However, it is difficult to exhaust all gaseous SnH₄ from the chamber and to prevent the SnH₄ from entering the exposure tool 200. To trap the SnH₄ or other debris, one or more debris collection mechanisms or devices 150 are employed in the chamber 105.

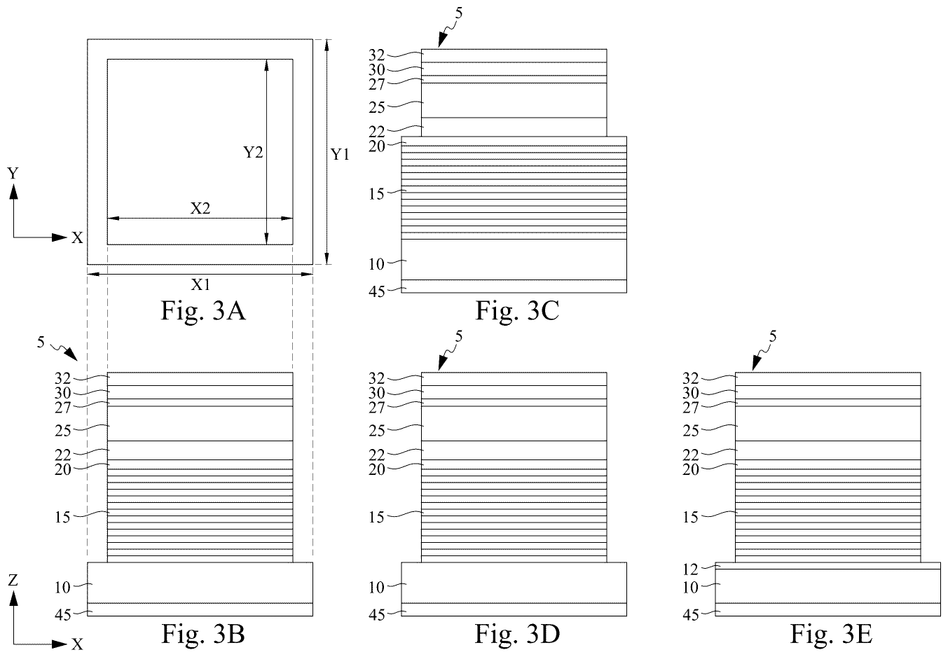

FIGS. 3A and 3B show an EUV reflective photomask blank according to an embodiment of the present disclosure. FIG. 3A is a plan view (viewed from the top) and FIG. 3B is a cross sectional view along the X direction.

In some embodiments, the EUV photomask with circuit patterns is formed from an EUV photomask blank 5. The EUV photomask blank 5 includes a substrate 10, a multilayer Mo/Si stack 15 of multiple alternating layers of silicon and molybdenum, a capping layer 20, a protection layer 22, an absorber layer 25, and a hard mask layer. In some embodiments, the hard mask layer includes a first hard mask layer 30 and a second hard mask layer 32. In other embodiments, the hard mask layer is a single layer. Further, a backside conductive layer 45 is formed on the backside of the substrate 10, as shown in FIG. 3B. In some embodiments, an oxide layer 27 is formed on the top surface of the absorber layer 25 as shown in FIG. 3B. In other embodiments, no oxide layer is formed on the top surface of the absorber layer 25 as shown in FIG. 3D.

The substrate 10 is formed of a low thermal expansion material in some embodiments. In some embodiments, the substrate is a low thermal expansion glass or quartz, such as fused silica or fused quartz. In some embodiments, the low thermal expansion glass substrate transmits light at visible wavelengths, a portion of the infrared wavelengths near the visible spectrum (near-infrared), and a portion of the ultraviolet wavelengths. In some embodiments, the low thermal expansion glass substrate absorbs extreme ultraviolet wavelengths and deep ultraviolet wavelengths near the extreme ultraviolet. In some embodiments, the size of the substrate 10 is 152 mm×152 mm having a thickness of about 20 mm. In other embodiments, the size of the substrate 10 is smaller than 152 mm×152 mm and equal to or greater than 148 mm×148 mm. The shape of the substrate 10 is square or rectangular.

In some embodiments, the functional layers above the substrate (the multilayer Mo/Si stack 15, the capping layer 20, the protection layer 22, the absorber layer 25, the first hard mask layer 30 and the second hard mask layer 32) have a smaller width than the substrate 10. In some embodiments, the size of the functional layers ranges from about 138 mm×138 mm to about 142 mm×142 mm. The shape of the functional layers is square or rectangular as seen in plan view in some embodiments.

In other embodiments, the protection layer 22, the absorber layer 25, the first hard mask layer 30 and the second hard mask layer 32 have a smaller size, ranging from about 138 mm×138 mm to about 142 mm×142 mm, than the substrate 10, the multilayer Mo/Si stack 15 and the capping layer 20 as shown in FIG. 3C. The smaller size of one or more of the functional layers can be formed by using a frame shaped cover having an opening ranging from about 138 mm×138 mm to about 142 mm×142 mm, when forming the respective layers by, for example, sputtering. In other embodiments, all of the layers above the substrate 10 have the same size as the substrate 10.

In some embodiments, the Mo/Si multilayer stack 15 includes from about 30 alternating layers each of silicon and molybdenum to about 60 alternating layers each of silicon and molybdenum. In certain embodiments, from about 40 to about 50 alternating layers each of silicon and molybdenum are formed. In some embodiments, the reflectivity is higher than about 70% for wavelengths of interest (e.g., 13.5 nm). In some embodiments, the silicon and molybdenum layers are formed by chemical vapor deposition (CVD), plasma-enhanced CVD (PECVD), atomic layer deposition (ALD), physical vapor deposition (PVD) (sputtering), or any other suitable film forming method. Each layer of silicon and molybdenum is about 2 nm to about 10 nm thick. In some embodiments, the layers of silicon and molybdenum are about the same thickness. In other embodiments, the layers of silicon and molybdenum are different thicknesses. In some embodiments, the thickness of each silicon layer is about 4 nm and the thickness of each molybdenum layer is about 3 nm.

In other embodiments, the multilayer stack 15 includes alternating molybdenum layers and beryllium layers. In some embodiments, the number of layers in the multilayer stack 15 is in a range from about 20 to about 100 although any number of layers is allowed as long as sufficient reflectivity is maintained for imaging the target substrate. In some embodiments, the reflectivity is higher than about 70% for wavelengths of interest e.g., 13.5 nm. In some embodiments, the multilayer stack 15 includes about 30 to about 60 alternating layers of Mo and Be. In other embodiments of the present disclosure, the multilayer stack 15 includes about 40 to about 50 alternating layers each of Mo and Be.

The capping layer 20 is disposed over the Mo/Si multilayer 15 to prevent oxidation of the multilayer stack 15 in some embodiments. In some embodiments, the capping layer 20 is made of ruthenium, a ruthenium alloy (e.g., RuNb, RuZr, RuZrN, RuRh, RuNbN, RuRhN, RuV or RuVN) or a ruthenium based oxide (e.g., RuO₂, RuNbO, RuVO, or RuON), having a thickness of from about 2 nm to about 10 nm. In certain embodiments, the thickness of the capping layer 20 ranges from about 2 nm to about 5 nm. In some embodiments, the capping layer 20 has a thickness of 3.5 nm±10%. In some embodiments, the capping layer 20 is formed by CVD, PECVD, ALD, PVD (e.g., sputtering), or any other suitable film forming method. In other embodiments, a Si layer is used as the capping layer 20.

In some embodiments, a protection (intermediate) layer 22 is formed between the capping layer 20 and the absorber layer 25. The protection layer 22 protects the capping layer 20 in some embodiments. In some embodiments, the protection layer 22 includes a Ta based material, such as TaB, TaO, TaBO or TaBN; silicon; a silicon-based compound (e.g., silicon oxide, silicon nitride, SiON, or MoSi); ruthenium; or a ruthenium-based compound (Ru or RuB). The protection layer 22 has a thickness of about 2 nm to about 20 nm in some embodiments. In some embodiments, the protection layer 22 is formed by CVD, PECVD, ALD, PVD, or any other suitable film forming method. In some embodiments, the protection layer 22 functions as an etching stop layer during a patterning operation of the absorber layer.

In other embodiments, the intermediate layer 22 is a photocatalytic layer that can catalyze hydrocarbon residues formed on the photomask into CO₂ and/or H₂O with EUV radiation. Thus, an in-situ self-cleaning of the mask surface is performed. In some embodiments, in the EUV scanner system, oxygen and hydrogen gases are injected into the EUV chamber to maintain the chamber pressure (e.g., at about 2 Pa). The chamber background gas can be a source of oxygen. In addition to the photocatalytic function, the photocatalytic layer is designed to have sufficient durability and resistance to various chemicals and various chemical processes, such as cleaning and etching. Ozonated water may be used to make the EUV reflective mask in a subsequent process. The ozonated water may damage the capping layer 20 made of Ru, which can result in a significant EUV reflectivity drop. Further after Ru oxidation, Ru oxide is easily etched away by an etchant, such as C1₂ or CF₄ gas. In some embodiments, the photocatalytic layer includes one or more of titanium oxide (TiO₂), tin oxide (SnO), zinc oxide (ZnO) and cadmium sulfide (CdS). The thickness of the photocatalytic layer 22 ranges from about 2 nm to about 10 nm in some embodiments, and ranges from about 3 nm to about 7 nm in other embodiments. When the thickness is too thin, the photocatalytic layer may not sufficiently function as an etch stop layer. When the thickness is too large, the photocatalytic layer may absorb the EUV radiation.

In some embodiments, the intermediate layer 22 is antireflective layer. The antireflective layer 22 is made of a silicon oxide in some embodiments, and has a thickness of from about 2 nm to about 10 nm. In other embodiments, a TaBO layer having a thickness ranging from about 12 nm to about 18 nm is used as the antireflective layer 22. In some embodiments, the thickness of the antireflective layer 22 ranges from about 3 nm to about 6 nm. In some embodiments, the antireflective layer 22 is formed by CVD, PECVD, ALD, PVD, or any other suitable film forming method.

The absorber layer 25 is disposed over the intermediate (protection) layer 22 in some embodiments. In some embodiments, the absorber layer 25 includes a Cr-based material, such as Cr, CrN, CrON, and/or CrCON. In the case of CrON or CrCON, a nitrogen amount is in a range from about 10 atomic % to about 30 atomic % in some embodiments. In some embodiments, the absorber layer 25 has a multilayered structure of Cr, CrN, CrON, and/or CrCON.

In certain embodiments, a CrN layer is used as the absorber layer 25. When the CrN layer is used, the nitrogen amount ranges from about 16 atomic % to about 40 atomic % in some embodiments. When the nitrogen amount ranges from about 16 atomic % to about 30 atomic %, the CrN absorber layer includes Cr and Cr₂N phases. When the nitrogen amount ranges from about 30 atomic % to about 33 atomic %, the CrN absorber layer substantially consists of a Cr₂N phase (e.g., more than 95 vol %). When the nitrogen amount ranges from about 33 atomic % to about 40 atomic %, the CrN absorber layer includes Cr₂N and CrN phases. The phases can be observed by an electron energy loss spectroscopy (EELS), a transmission electron microscope (TEM), and/or an X-ray diffraction (XRD) analysis. In some embodiments, the two phases form a solid solution.

In some embodiments, a nitrogen concentration in the absorber layer 25 is not uniform. In some embodiments, the nitrogen concentration is higher in the middle or the center of the absorber layer 25 than a surface region of the absorber layer 25. In some embodiments, the CrN absorber layer includes one or more impurities other than Cr and N in an amount of less than about 5 atomic %. In some embodiments, the absorber layer 25 further includes one or more elements of Co, Te, Hf, and/or Ni.

In some embodiments, the thickness of the absorber layer 25 ranges from about 20 nm to about 50 nm, and ranges from about 35 nm to about 46 nm in other embodiments.

The oxide layer 27 includes one or more of Cr₂O₃ or CrO₂ in some embodiments. In some embodiments, the oxide layer 27 is formed during the manufacturing operation of the mask blank. In some embodiments, the thickness of the oxide layer 27 ranges from about 1 nm to about 3 nm. In some embodiments, as shown in FIG. 3D, no oxide layer is formed.

The first hard mask layer 30 is disposed over the oxide layer 27 in some embodiments. The first hard mask layer 30 is formed over the absorber layer 25 in some embodiments. In some embodiments, the first hard mask layer 30 is made of a Ta based material, such as TaB, TaO, TaBO or TaBN. In other embodiments, the first hard mask layer 30 is made of silicon, a silicon-based compound (e.g., silicon oxide, silicon nitride, SiON, or MoSi), ruthenium or a ruthenium-based compound (Ru or RuB). In some embodiments, the first hard mask layer 30 is made of the same or similar material as the protection layer 22. The first hard mask layer 30 has a thickness of about 2 nm to about 20 nm in some embodiments. In some embodiments, the first hard mask layer 30 is formed by CVD, PECVD, ALD, PVD, or any other suitable film forming method.

The second hard mask layer 32 is disposed over the first hard mask layer 30 in some embodiments. In some embodiments, the second hard mask layer 32 is made of one or more of GaN, CrON, CrCON, silicon oxide, SiCO, and/or yttrium oxide. The second hard mask layer 32 has a thickness of about 2 nm to about 20 nm in some embodiments. The second hard mask layer 32 is smaller or larger than the thickness of the first hard mask layer, in some embodiments. In some embodiments, the second hard mask layer 32 is formed by CVD, PECVD, ALD, PVD, or any other suitable film-forming method.

In some embodiments, the second hard mask layer 32 is made of a material having a higher etching rate for a plasma including chlorine and oxygen than a material of the first hard mask layer 30. In some embodiments, the first hard mask layer 30 is made of a material having a higher etching rate for a plasma including fluorine than a material of the second hard mask layer 32.

In some embodiments, one or more of the functional layers above the substrate (the multilayer Mo/Si stack 15, the capping layer 20, the protection layer 22, the absorber layer 25, the oxide layer 27, the first hard mask layer 30 and the second hard mask layer 32) have a poly-crystalline structure (e.g., nano-crystalline structure) or an amorphous structure.

In some embodiments, a backside conductive layer 45 is disposed on a second main surface of the substrate 10 opposing the first main surface of the substrate 10 on which the Mo/Si multilayer 15 is formed. In some embodiments, the backside conductive layer 45 is made of TaB (tantalum boride) or other Ta-based conductive material. In some embodiments, the tantalum boride is crystalline. The crystalline tantalum boride includes TaB, Ta₅B₆, Ta₃B₄, and TaB₂. In other embodiments, the tantalum boride is polycrystalline or amorphous. In other embodiments, the backside conductive layer 45 is made of a Cr-based conductive material (CrN or CrON). In some embodiments, the sheet resistance of the backside conductive layer 45 is equal to or smaller than 20 Ω/□. In certain embodiments, the sheet resistance of the backside conductive layer 45 is equal to or more than 0.1 Ω/□. In some embodiments, the surface roughness Ra of the backside conductive layer 45 is equal to or smaller than 0.25 nm. In certain embodiments, the surface roughness Ra of the backside conductive layer 45 is equal to or more than 0.05 nm. Further, in some embodiments, the flatness of the backside conductive layer 45 is equal to or less than 50 nm (within the EUV photo mask). In some embodiments, the flatness of the backside conductive layer 45 is more than 1 nm. A thickness of the backside conductive layer 45 ranges from about 50 nm to about 400 nm in some embodiments. In other embodiments, the backside conductive layer 45 has a thickness of about 50 nm to about 100 nm. In certain embodiments, the thickness ranges from about 65 nm to about 75 nm. In some embodiments, the backside conductive layer 45 is formed by atmospheric CVD, low pressure CVD, PECVD, laser-enhanced CVD, ALD, molecular beam epitaxy (MBE), PVD including thermal deposition, pulsed laser deposition, electron-beam evaporation, ion beam assisted evaporation, and sputtering, or any other suitable film forming method. In cases of CVD, source gases include TaCl₅ and BCl₃ in some embodiments.

In some embodiments, as shown in FIG. 3E, a substrate protection layer 12 is formed between the substrate 10 and the multilayer stack 15. In some embodiments, the substrate protection layer 12 is made of Ru or a Ru compound, such as RuO, RuNb, RuNbO, RuZr, and RuZrO. In some embodiments, the substrate protection layer 12 is made of the same material as or different material from the capping layer 20. The thickness of the substrate protection layer 12 ranges from about 2 nm to about 10 nm in some embodiments.

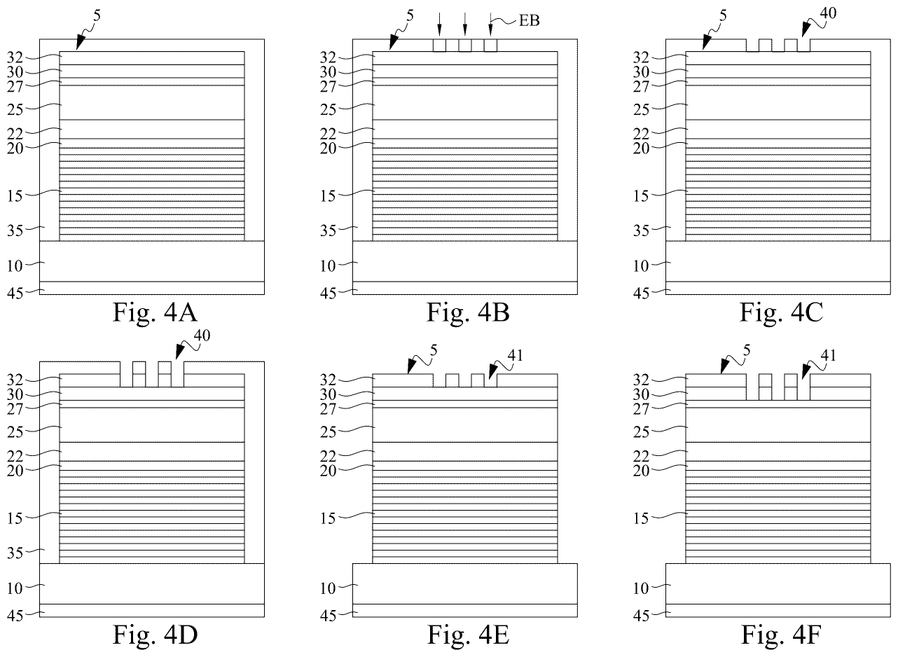

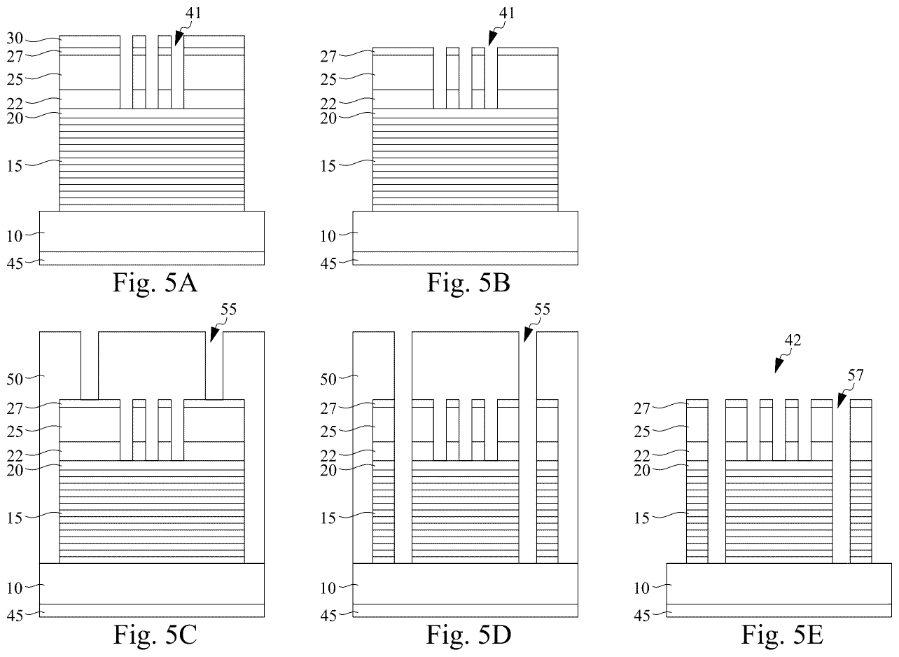

FIGS. 4A-4F and 5A-5E schematically illustrate a method of fabricating an EUV photomask for use in EUV lithography. It is understood that additional operations can be provided before, during, and after the processes shown by FIGS. 4A-5E, and some of the operations described below can be replaced or eliminated for additional embodiments of the method. The order of the operations/processes may be interchangeable.

In the fabrication of an EUV photomask, a first photoresist layer 35 is formed over the second hard mask layer 32 of the EUV photomask blank 5 in some embodiments, as shown in FIG. 4A, and the photoresist layer 35 is selectively exposed to actinic radiation EB as shown in FIG. 4B. Before the first photoresist layer 35 is formed, the EUV photomask blank is subject to inspection in some embodiments. The selectively exposed first photoresist layer 35 is developed to form a pattern 40 including at least one opening in the first photoresist layer 35 as shown in FIG. 4C. In some embodiments, the actinic radiation EB is an electron beam or an ion beam. In some embodiments, the pattern 40 corresponds to a pattern of semiconductor device features for which the EUV photomask will be used to form in subsequent operations. In some embodiments, the thickness of the first photo resist layer on the second hard mask layer 32 ranges from about 500 nm to about 1000 nm.

Next, the pattern 40 in the first photoresist layer 35 is extended into the second hard mask layer 32 forming a pattern 41 including at least one opening in the second hard mask layer 32 exposing portions of the first hard mask layer 30, as shown in FIG. 4D. The pattern 41 extended into the second hard mask layer 32 is formed by etching, in some embodiments, using a suitable wet or dry etchant that is selective to the first hard mask layer 30. In some embodiments, a plasma dry etching operation using a chlorine containing gas (e.g., Cl₂, HCl, BCl, and CCl₄) and an oxygen containing gas (e.g., O₂) is used to pattern the second hard mask layer 32. In some embodiments, the material of the first hard mask layer 30 is selected to have a higher etching resistance (lower etching rate) against the plasma dry etching operation using chorine and oxygen, and the etching substantially stops at the first hard mask layer 30. After the pattern 41 in the second hard mask layer 30 is formed, the first photoresist layer 35 is removed by a photoresist stripper to expose the upper surface of the second hard mask layer 32, as shown in FIG. 4E.

Next, the pattern 41 including at least one opening in the second hard mask layer 32 is extended into the first hard mask layer 30 exposing portions of the oxide layer 27 in some embodiments, as shown in FIG. 4F. The pattern 41 extended into the first hard mask layer 30 is formed by etching, in some embodiments, using a suitable wet or dry etchant that is selective to the oxide layer 27. In some embodiments, a plasma dry etching operation using a fluorine containing gas (e.g., a fluorocarbon (CF₄, CHF₃, etc.) and SF₆) is used to pattern the first hard mask layer 30. In some embodiments, the material of the absorber layer 27 is selected to have a higher etching resistance (lower etching rate) against the plasma dry etching operation using fluorine, and the etching substantially stops at the oxide layer 27.

Then, the pattern 41 in the first and second hard mask layers 30, 32 is extended into the absorber layer 25 forming a pattern 41 in the absorber layer 25 exposing portions of the intermediate layer 22 in some embodiments, as shown in FIG. 5A. The oxide layer 27 and the absorber layer 25 are etched by using a suitable wet or dry etchant that is selective to the first hard mask layer 30 and/or the intermediate layer 22. In some embodiments, the material of the intermediate layer 22 is selected to have a higher etching resistance (lower etching rate) against the plasma dry etching operation using chlorine and oxygen, and the etching substantially stops at the intermediate layer 22. In some embodiments, as shown in FIG. 5A, the second hard mask layer 32 is removed during the etching of the oxide layer 27 and the absorber layer 25. In particular, when the second hard mask layer 32 is made of a Cr based material (e.g., CrN, CrON, or CrCON), the second hard mask layer 32 is removed during the etching of the oxide layer 27 and the absorber layer 25. If the second hard mask layer 32 remains after etching the absorber layer 25, an additional removal operation of the second hard mask layer 32 is performed in some embodiments by using a suitable wet or dry etching.

Then, the first hard mask layer 30 is removed together with a part of the intermediate layer 22 at the bottom of the pattern openings, as shown in FIG. 5B. In some embodiments, the etching is wet etching and/or dry etching. In some embodiments, a plasma dry etching operation using a fluorine containing gas (e.g., a fluorocarbon (CF₄, CHF₃, etc.) and SF₆) is used to remove the first hard mask layer 30 and the intermediate layer 22. In particular, when the first hard mask layer 30 is made of the same or similar material as the intermediate layer 22, the first hard mask layer 30 is removed together with the intermediate layer 22. In some embodiments, the material of the capping layer 20 is selected to have a higher etching resistance (lower etching rate) against the plasma dry etching operation using fluorine, and the etching substantially stops at the capping layer 20.

As shown in FIG. 5C, a second photoresist layer 50 is formed over the oxide layer 27 and the absorber layer 25 filling the pattern 42 in the absorber layer 25. The second photoresist layer 50 is selectively exposed to actinic radiation such as an electron beam, ion beam, or UV radiation. The selectively exposed second photoresist layer 50 is developed to form a pattern 55 in the second photoresist layer 50 as shown in FIG. 5C. The pattern 55 corresponds to a black border surrounding the circuit patterns. A black border is a frame shape area created by removing all the multilayers on the EUV photomask in the region around a circuit pattern area. The black border pattern can be created to prevent exposure of adjacent fields when printing an EUV photomask on a wafer. The width of the black border ranges from about 1 mm to about 5 mm in some embodiments.

Next, the pattern 55 in the second photoresist layer 50 is extended into the oxide layer 27, the absorber layer 25, the optional intermediate layer 22, the capping layer 20, and the Mo/Si multilayer 15 forming a pattern 57 (see, FIG. 5E) in the oxide layer 27, the absorber layer 25, the intermediate layer 22, the capping layer 20, and the Mo/Si multilayer 15 exposing portions of the substrate 10, in some embodiments, as shown in FIG. 5D. The pattern 57 can be formed by etching using one or more suitable wet or dry etchants that are selective to each of the layers that are etched. In some embodiments, plasma dry etching is used.

Then, the second photoresist layer 50 is removed by a suitable photoresist stripper to expose the upper surface of the oxide layer 27 to form a photomask with circuit patterns 42, as shown in FIG. 5E. The black border pattern 57 in the oxide layer 27, the absorber layer 25, the intermediate layer 22, the capping layer 20, and the Mo/Si multilayer 15 defines a black border of the photomask in some embodiments of the disclosure. Further, the photomask undergoes a cleaning operation, inspection, and the photomask is repaired as necessary, to provide the finished photomask.

The etching of absorber layer 25 according to embodiments of the disclosure will be explained in further detail. Etching gases used in the etching of the absorber layer include a mixture of chlorine and oxygen, or a fluorocarbon gas and oxygen. In some embodiments, the fluorocarbon gas includes C_{X}H_{Y}F_{Z}, where 0<X≤10, 0≤Y≤12, and 0<Z≤12. In some embodiments, a plasma dry etching operation using a chlorine-containing gas (e.g., Cl₂, HCl, BCl, and CCl₄) and an oxygen-containing gas (e.g., O₂) or a fluorine-containing gas (e. g, CF₄, CHF₃, C₂F₆, and C₄F₈) and the oxygen-containing gas is used to pattern the absorber layer 25.

During the etching of the absorber layer etching byproducts are formed on the sidewalls of the openings formed in the absorber layer. For example, when the absorber layer 25 is made of a Cr-based material, such as CrN, various reaction byproducts of chromium and the etching gases are formed on the sidewalls of the openings. In some embodiments, the byproducts deposited on the sidewalls include a layer of CrOₓF_{y} or CrOₓCl_{y}, where 0<x≤10, and 0<y≤10. In addition, when the hard mask layer includes a second hard mask layer made of Ta-based material, such as TaBO or TaBN, and/or includes an intermediate layer made of a Ta-based material, byproducts of the etching gases and the Ta-based material may be formed on the sidewalls of the openings in the absorber layer.

Examples of reactions of the hard mask layer and intermediate layers with the etching gases and byproducts formed on the sidewalls of the openings are shown below. The reactions occurring during the etching and byproducts formed are not limited to the examples below:

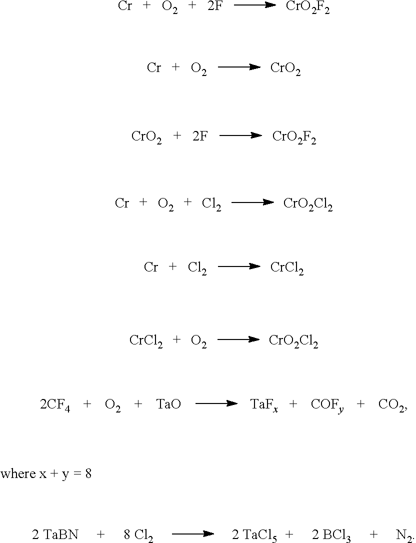

The byproduct sidewalls may have shallow footing angles (e.g., less than about 75°) at the bottom portion of the opening, thus further reducing the size of the opening. The etching byproduct sidewalls formed during the etching operation can degrade the resolution of the mask, and thus, degrade the patterns formed in photoresist layers using the mask.

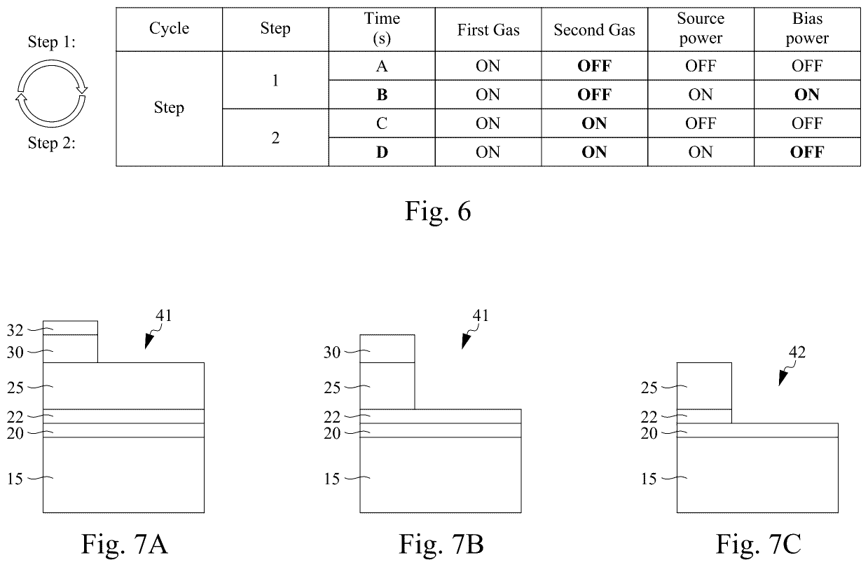

In embodiments of the disclosure, the etching gases are cycled during the etching operation to limit the growth of the byproduct sidewalls in the openings when etching the absorber layer. The cycle of applying the etching gases according to some embodiments is shown in FIG. 6. In step 1, the first etching gas is applied, and in step 2, the first and second etching gases are applied. In some embodiments, step 1 and step 2 are repeatedly cycled until the etching operation is completed. In some embodiments, a first etching gas is introduced into the etching chamber for a first period of time A in step 1, then the source power and bias power are turned on for a second period of time B in step 1. After a first and second periods of time, the source power and bias power are turned off, and then the first etching gas and a second etching gas is introduced into the etching chamber for a third period of time C in step 2. Next, the source power is turned without turning on the bias power for a fourth period of time D in step 2. In some embodiments, an over etch operation is performed after the repetitive etch cycling operation.

In some embodiments, the first etching gas is an oxygen-containing gas, such as O₂ and the second etching gas is a chlorine-containing gas, such as Cl₂ or a fluorine-containing gas, such as C_{X}H_{Y}F_{Z}, where 0<X≤10, 0≤Y≤12, and 0<Z≤12. In some embodiments, a noble or inert gas, such as Ar, is included with the first etching gas and/or the second etching gas to assist in plasma stabilization and control the etch rate and selectivity. In some embodiments, the source power ranges from about 50 W to about 3000 W, and in other embodiments, the source power ranges from about 100 W to about 2500 W. In some embodiments, the bias power ranges from about 5 V to about 500 V, and in other embodiments, the bias power ranges from about 10 V to about 400 V. At source and bias powers outside the disclosed ranges there may be insufficient etching or loss of control of the etching operation a resulting unsatisfactory etched pattern profile.

In some embodiments, the first period of time A ranges from 0 to about 100 s, the second period of time B ranges from greater than 0 s to about 100 s, the third period of time C ranges from 0 s to about 100 s, and the fourth period D ranges from greater than 0 s to about 100 s. In some embodiments, the first period of time A and/or the third period of time C are 0 s. In other words, the introduction of the first etching gas occurs substantially simultaneously with the turning on of the source power and the bias power in step 1, and/or the introduction of the second etching gas occurs substantially simultaneously with the turning on of the source power in step 2.In some embodiments, the length of step 1, where the first etching gas is applied, ranges from about 3 s to about 30 s; and the length of step 2, where the first and second etching gases are applied, ranges from about 2 s to about 20 s. In an embodiment, the length of step 1 is 7±2 s, and the length of step 2 is 5±2 s. In some embodiments, an over-etch operation is performed for a time period ranging from about 5 s to about 50 s. In an embodiment, the over-etch operation is performed for 30±2 s. At etching time periods outside the disclosed ranges, there may be insufficient etching or loss of control of the etching operation, and a resulting unsatisfactory etched pattern profile.

In some embodiments, the pressure inside the etching chamber ranges from about 1 mTorr to about 100 mTorr. At etching pressures outside the disclosed ranges, there may be insufficient etching or loss of control of the etching operation, and a resulting unsatisfactory etched pattern profile.

FIGS. 7A, 7B, and 7C schematically illustrate a detailed view of forming an opening 42 in the absorber layer 25. FIG. 7A shows opening 41 formed in the first and second hard mask layers 30, 32. The second hard mask layer is removed, as shown in FIG. 7B, and the cyclical etching operation disclosed herein is performed to extend the opening 41 through the absorber layer 25. Then the first hard mask layer is removed, and the intermediate layer is etched in some embodiments, to form the circuit pattern opening 42 in the mask, as shown in FIG. 7C.

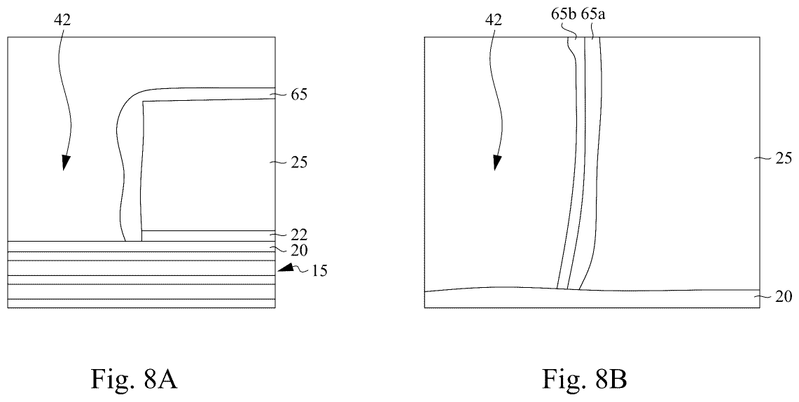

FIG. 8A shows a cross sectional detailed view of a circuit pattern opening 42 formed in an absorber layer 25 of an EUV photomask according to an embodiment of the disclosure. As shown, an etching byproduct sidewall 65 is formed over the sidewall of the opening 42 in the absorber layer. In some embodiments, the etching byproduct sidewall extends over an upper surface of the absorber layer 25.

FIG. 8B shows a cross sectional detailed view of a sidewall formed in the opening 42 in the absorber layer 25 according to an embodiment of the disclosure. In some embodiments, the sidewall includes two or more sidewalls depending on the number of different etching operations and different etching gases used. For example, in some embodiments, the main etching operation cycles a first oxygen etching step and a second oxygen and C_{X}H_{Y}F_{Z} etching step, as disclosed herein. In such a case, the sidewall 65 would be made of CrO₂F₂. In other embodiments, the main etching operation forms a first sidewall 65a made of CrO₂F₂. The main etching operation is the followed by an over etch using a mixture of Cl₂ and O₂, resulting in a second sidewall 65b made of CrO₂Cl₂. In some embodiments, a thickness of the first sidewall 65a ranges from about 1 nm to about 3 nm, and a thickness of the second sidewall 65b ranges from about 0 nm to about 3 nm. In an embodiment, the thickness of the first sidewall is 2±1 nm and the thickness of the second sidewall is 1.7±1 nm.

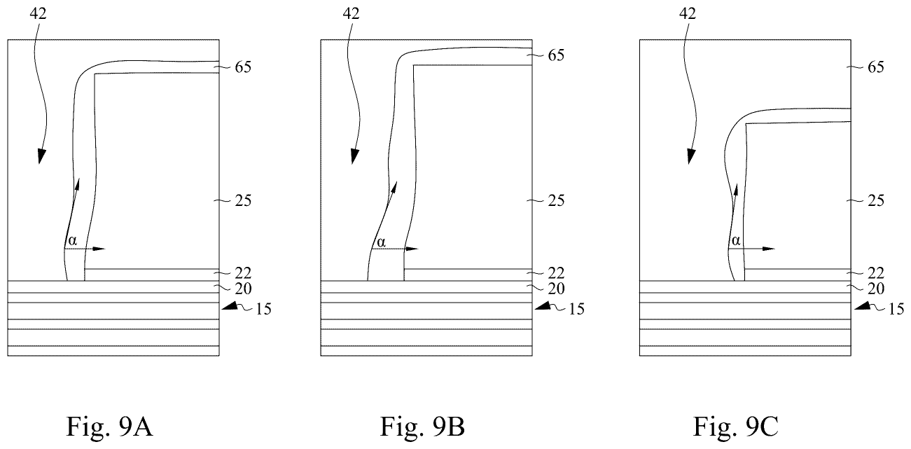

FIGS. 9A, 9B, and 9C show cross sectional detailed views of sidewalls 65 in the openings 42 formed in the absorber layer 25 according to embodiments of the disclosure. FIG. 9A shows an embodiment where the etching operation includes the alternate cycling of an O₂ etching step and an O₂+C_{X}H_{Y}F_{Z} etching step. As shown in FIG. 9A, a footing angle α of 77.8±2° is formed in this embodiment. FIG. 9B illustrates an embodiment where the alternate cycling of the O₂ etch step and the O₂+C_{X}H_{Y}F_{Z} etching step is followed by about a 30 s over etch using the O₂+C_{X}H_{Y}F_{Z} etching gas mixture. As shown in FIG. 9B, a footing angle α of 77.4±2° is formed in this embodiment. FIG. 9C illustrates an embodiment where the alternate cycling of the O₂ etch step and the O₂+C_{X}H_{Y}F_{Z} etching step is followed by about a 30 s over etch using O₂+Cl₂ etching gas mixture. As shown in FIG. 9C, a footing angle α of 88.5±2° is formed in this embodiment.

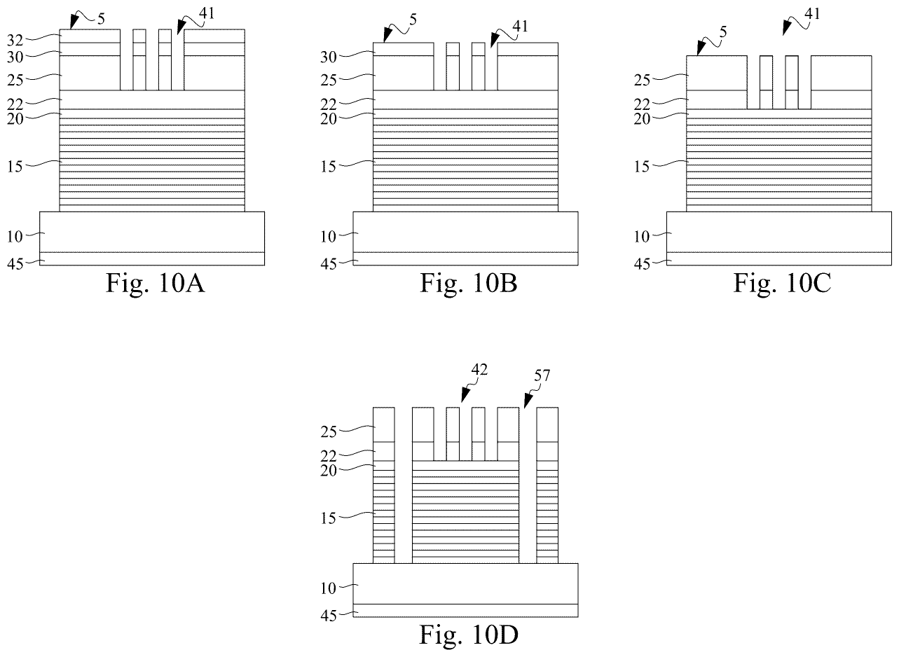

FIGS. 10A, 10B, 10C, and 10D show cross sectional views of a multilayer structure of an absorber layer according to another embodiment of the present disclosure. It is understood that additional operations can be provided before, during, and after processes shown by FIGS. 10A-10D, and some of the operations described below can be replaced or eliminated, for additional embodiments of the method. The order of the operations/processes may be interchangeable. Materials, configurations, processes and/or dimensions as explained with respect to the foregoing embodiments may be employed in the following embodiments and detailed description thereof may be omitted. The embodiment of FIGS. 10A, 10B, and 10C is applied to a mask blank as shown in FIG. 3D, where no oxide layer is formed on the absorber layer 25. FIG. 10A shows a structure after the hard mask layer 30 is patterned similar to FIG. 4F. The etching of the first hard mask layer 30 substantially stops at the absorber layer 25.

Then, the absorber layer 25 is patterned (etched) by using the patterned first and second hard mask layers as shown in FIG. 10B. In some embodiments, as shown in FIG. 10B, the second hard mask layer 32 is removed during the etching of the absorber layer 25. In some embodiments, when the intermediate layer 22 is made of the same material as or similar material to the first hard mask layer 30, the etching substantially stops at the intermediate layer 22. Then, as shown in FIG. 10C, the first hard mask layer 30 is removed together with a part of the intermediate layer 22 at the bottom of the opening patterns of the absorber layer 25.

FIG. 10D shows a cross sectional view of a finished EUV photo mask according to embodiments of the present disclosure. In some embodiments, the EUV photo mask with circuit patterns 42 as shown in FIG. 10D includes a substrate 10, a multilayer Mo/Si stack 15 of multiple alternating layers of silicon and molybdenum, a capping layer 20 and a patterned absorber layer 25. Further, a black border pattern 57 is formed in the absorber layer 25, the capping layer 20, and the Mo/Si multilayer 15, and a backside conductive layer 45 is formed on the backside of the substrate 10. In some embodiments, the patterned absorber layer 25 includes a CrN layer or a nitrogen rich CrON or CrCON layer with a nitrogen amount in a range from about 10 atomic % to about 30 atomic % in some embodiments.

Generally, a Cr-based material (CrN, CrON, or CrCON) has a high EUV absorption (extinction) coefficient k. For example, CrN has a k-value of 0.0387, which is higher than the k value (0.031) of TaBN and the k value (0.027) of TaBO. Accordingly, it is possible to reduce the thickness of the absorber layer (e.g., from 70 nm of TaBN to 46 nm of CrN), which can suppress three-dimensional effects of the patterned absorber layer. However, a CrN layer or a nitrogen rich CrON or CrCON layer is difficult to etch because of its low etching rate. In some embodiments, two hard mask layers are used to pattern the absorber layer, to assist in the controlling the pattern profile of the etched patterns. Thus, it is possible to further improve the resolution of EUV lithography and to provide a mask with a higher EUV absorption coefficient.

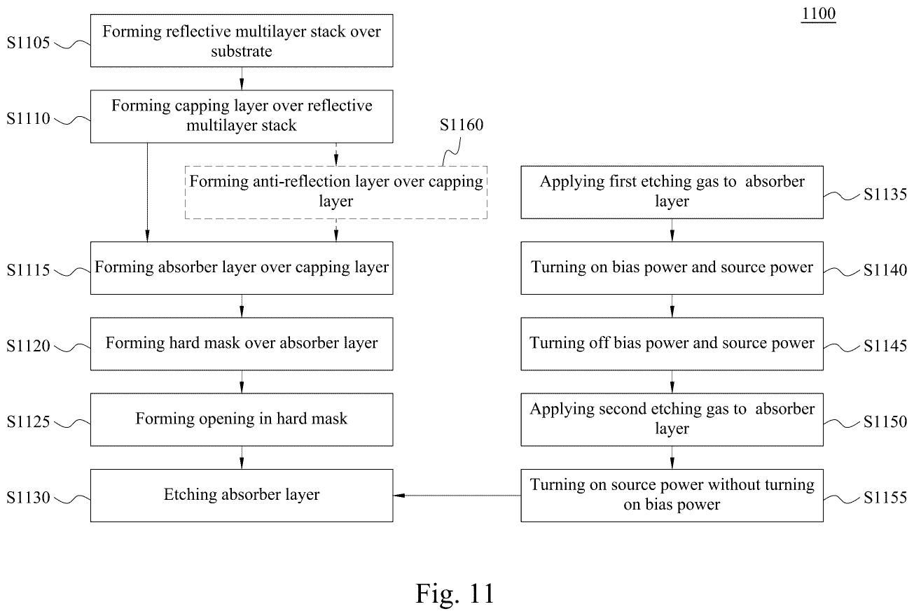

FIG. 11 shows a flow chart of a method 1100 of manufacturing an EUV photomask according to embodiments of the present disclosure. In operation S1105, A reflective multilayer stack 15 is formed over a substrate 10. A capping layer 20 is formed over the reflective multilayer stack 15 in operation S1110. Then, in operation S115, an absorber layer 25 is formed over the capping layer 20, and a hard mask 30, 32 is formed over the absorber layer 25 in operation S1120. In operation S1125, an opening 41 is formed in the hard mask 30, 32 exposing the absorber layer 25 in operation S1125. The absorber layer is etched in operation S1130 using the hard mask 30, 32 as an etching mask. In operation S1130, etching the absorber layer 25 includes in order: operation S1135, applying a first etching gas to the absorber layer; operation S1140, turning on a bias power and a source power; operation S1145, turning off the bias power and the source power; operation S1150, applying a second etching gas to the absorber layer, wherein the first etching gas and the second etching gas are different; and operation S1155, turning on the source power without turning on the bias power. In some embodiments, an anti-reflection layer 22 is formed over the capping layer in operation S1160 before forming the absorber layer in operation S1115.

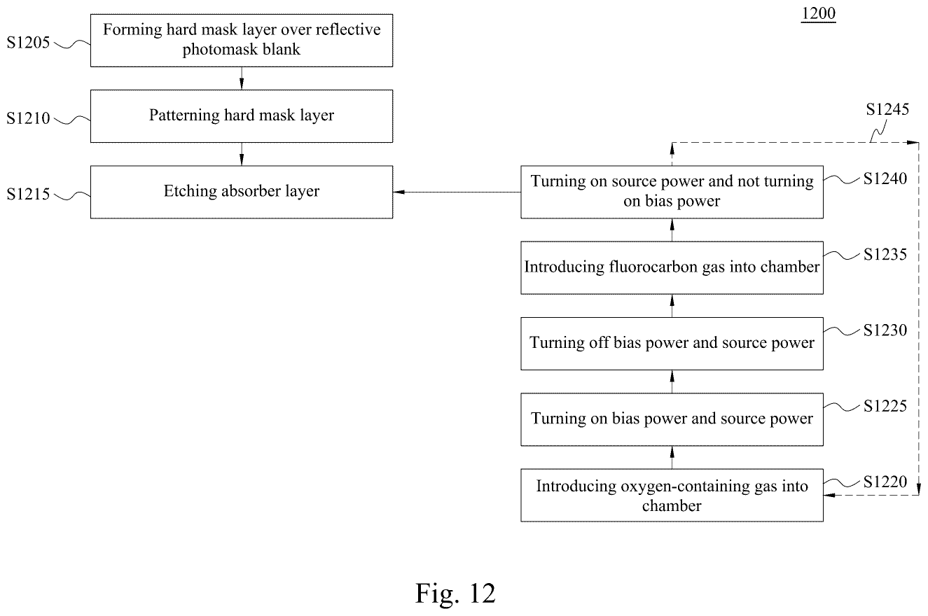

FIG. 12 shows a flow chart of a method 1200 of manufacturing an EUV photomask according to embodiments of the present disclosure. In operation S1205, a hard mask layer 30, 32 is formed over a reflective photomask blank 5. The reflective photomask blank 5 includes: a reflective multilayer stack 15 disposed over a substrate 10, a capping layer 20 disposed over the reflective multilayer stack 15, and an absorber layer 25 disposed over the capping layer 20. In operation S1210, the hard mask layer 30, 32 is patterned to form an opening 41 in the hard mask layer. The absorber layer 25 is etched in a chamber using the patterned hard mask layer as an etching mask in operation S1215. Etching the absorber layer in operation S1215 includes operations of: operation S1220, a) introducing an oxygen-containing gas into the chamber; operation S1225, b) turning on a bias power and a source power for a first period of time; operation S1230, c) turning off the bias power and the source power; operation S1235, d) introducing a fluorocarbon gas into the chamber; and operation S1240, e) turning on the source power for a second period of time and not turning on the bias power during the second period of time. In some embodiments, the method 1200 includes operation S1245 of repeating operations a) to e).

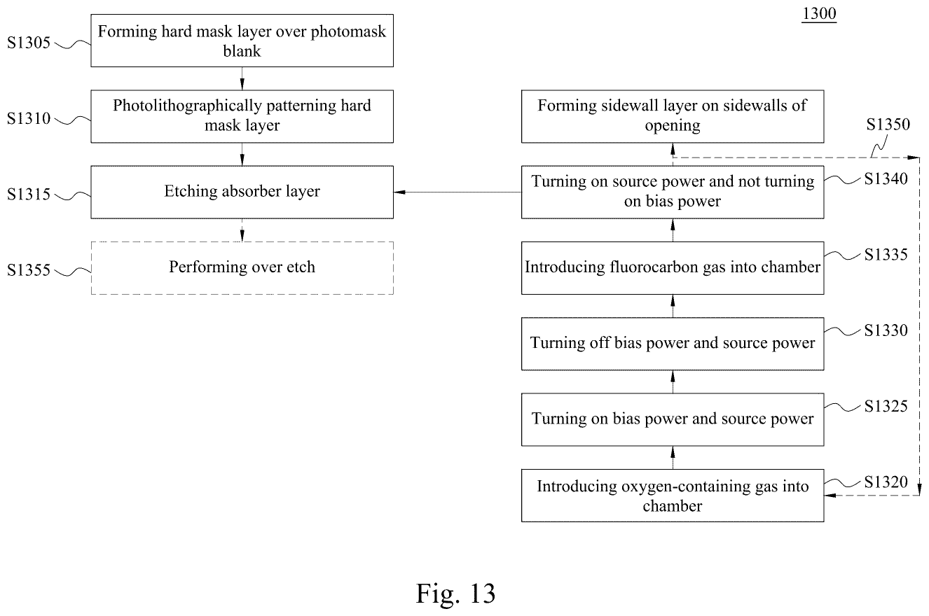

FIG. 13 shows a flow chart of a method 1300 of manufacturing an EUV photomask according to embodiments of the present disclosure. The method 1300 includes operation S1305 of forming a hard mask layer 30, 32 including a first tantalum compound over a photomask blank 5. The photomask blank includes: a reflective multilayer stack 15 disposed over a substrate 10; a capping layer 20 disposed over the reflective multilayer stack 15; an intermediate layer 22 comprising a second tantalum compound disposed over the capping layer 20; and an absorber layer 25 disposed over the intermediate layer 22. In operation S1310, the hard mask layer 30, 32 is photolithographically patterned to expose a portion of the absorber layer 25. The absorber layer is etched in a chamber using the patterned hard mask layer as an etching mask in operation S1315 to form an opening 42 in the absorber layer 25. Etching the absorber layer in operation S1315 includes the operations of: S1320, a) introducing an oxygen-containing gas into the chamber; S1325, b) turning on a bias power and a source power for a first period of time; S1330, c) turning off the bias power and the source power; S1335, d) introducing a fluorocarbon gas into the chamber; S1340, e) turning on the source power for a second period of time and not turning on the bias power during the second period of time; and S1345, f) forming a sidewall layer comprising a reaction product of the oxygen-containing gas, the fluorocarbon gas, and the absorber layer on sidewalls of the opening. In some embodiments, the method 1300 includes an operation S1350 of repeating operations a), b), c), d), and e). In some embodiments, the method 1300 includes performing an over-etch operation using an over-etch gas in operation S1355.

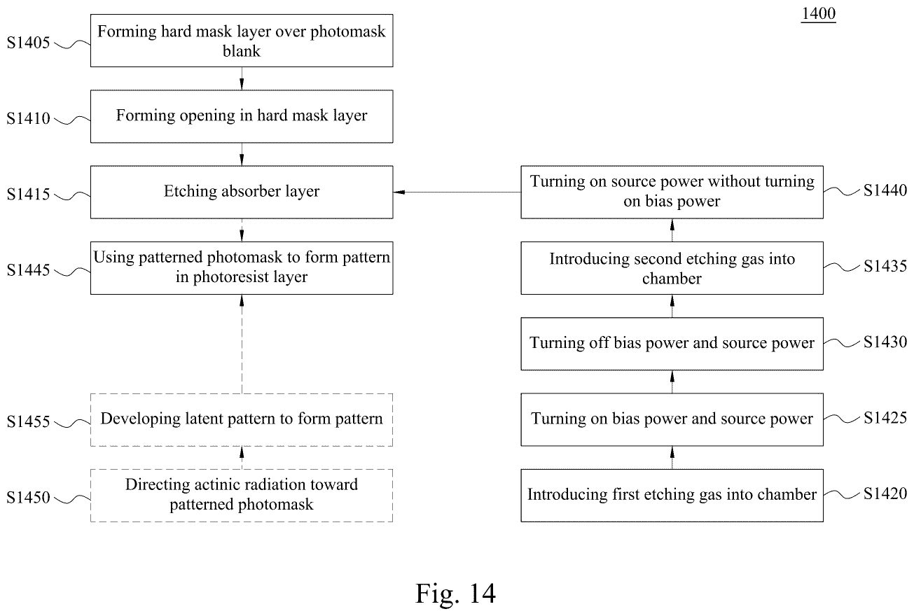

FIG. 14 shows a flow chart of a method 1400 of manufacturing a semiconductor device according to embodiments of the present disclosure. In operation S1405, a hard mask layer 30, 32, is formed over a photomask blank 5. The photomask blank 5 includes: a reflective multilayer stack 15 disposed over a substrate 10, a capping layer 20 disposed over the reflective multilayer stack 15, and an absorber layer 25 disposed over the capping layer 20. An opening 41 is formed in the hard mask layer in operation S1410 exposing the absorber layer 25. The absorber layer 25 is etched in operation S1415 using the hard mask layer as an etching mask to form a patterned photomask. Etching the absorber layer includes the operations: S1420, introducing a first etching gas into a chamber containing the photomask blank 5; S1425, turning on a bias power and a source power for a first time period; S1430, turning off the bias power and the source power after the first time period; S1435, introducing a second etching gas into the chamber after turning off the bias power and source power, wherein the first etching gas and the second etching gas are different; and S1440, turning on the source power without turning on the bias power for a second period of time after introducing the second etching gas. In operation S1445, the patterned photomask is used to form a pattern in a photoresist layer disposed over a semiconductor substrate. In some embodiments, using the patterned photomask to form a pattern in the photoresist layer includes operation S1450, directing actinic radiation toward the patterned photomask such that the actinic is reflected off the patterned photomask and the reflected actinic radiation is directed towards the photoresist layer to form a latent pattern in the photoresist layer; and operation S1455, developing the latent pattern to form a pattern in the photoresist layer.

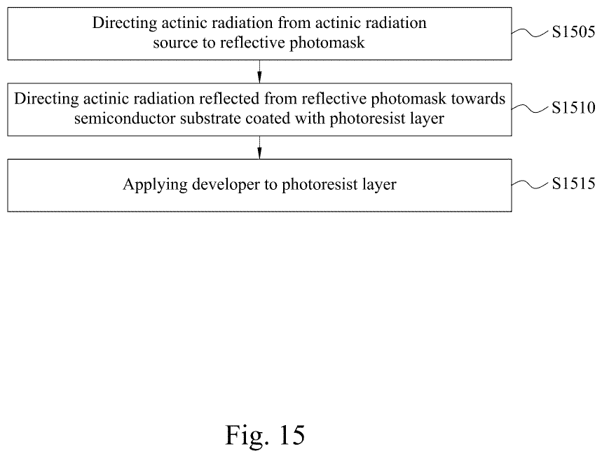

FIG. 15 shows a flow chart of a method 1500 of manufacturing a semiconductor device according to embodiments of the present disclosure. In operation S1505, actinic radiation is directed from an actinic radiation source to a reflective photomask. The reflective photomask includes: a reflective multilayer stack 15 disposed over a substrate 10, a capping layer 20 disposed over the reflective multilayer stack 15, a patterned absorber layer 25 including at least one pattern feature disposed over the capping layer, and a sidewall layer disposed over sidewalls of the at least one pattern feature. The sidewalls include a layer of CrOₓF_{y} or CrOₓCl_{y}, where 0<x≤10, and 0<y≤10. In operation S1510, patterned actinic radiation reflected from the reflective photomask is directed towards a semiconductor substrate coated with a photoresist layer to form a latent image in the photoresist layer. Then a developer is applied to the photoresist layer to develop the latent image and form a pattern in the photoresist layer in operation S1515.

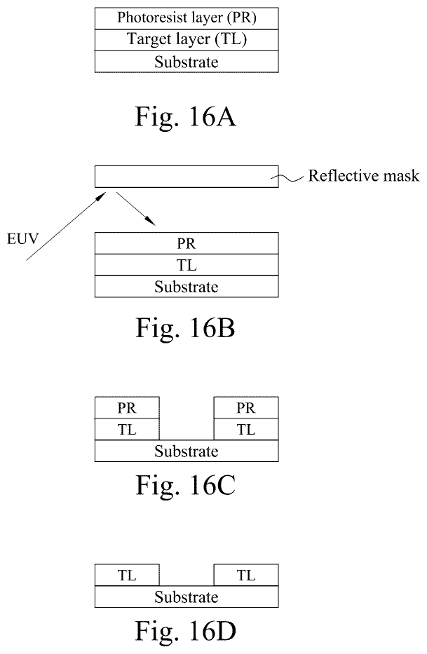

FIGS. 16A, 16B, 16C, and 16D show a sequential manufacturing operation of the method of making a semiconductor device in accordance with embodiments of present disclosure. A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material.

As shown in FIG. 16A, a target layer (TL) to be patterned is formed over the semiconductor substrate. In certain embodiments, the target layer is the semiconductor substrate. In some embodiments, the target layer includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer is formed over an underlying structure, such as isolation structures, transistors or wirings. A photoresist layer PR is formed over the target layer TL, as shown in FIG. 16A. The photoresist layer is sensitive to the radiation from the exposing source during a subsequent photolithography exposing process. In the present embodiment, the photoresist layer is sensitive to EUV light used in the photolithography exposing process. The photo resist layer may be formed over the target layer by spin-on coating or other suitable technique. The coated photoresist layer may be further baked to drive out solvent in the photoresist layer.

The photoresist layer is subsequently patterned using an EUV reflective mask as set forth above, as shown in FIG. 16B. The patterning of the photoresist layer includes performing a photolithography exposing process by an EUV exposing system using the EUV mask. During the exposing process, the integrated circuit (IC) design pattern defined on the EUV mask is imaged to the photoresist layer to form a latent pattern thereon.

The patterning of the photoresist layer further includes developing the exposed photoresist layer to form a patterned photoresist layer having one or more openings, as shown in FIG. 16C. In one embodiment where the photoresist layer is a positive tone photoresist layer, the exposed portions of the photoresist layer are removed during the developing process. The patterning of the photoresist layer may further include other process steps, such as various baking steps at different stages. For example, a post-exposure-baking (PEB) process may be implemented after the photolithography exposing process and before the developing process.

As shown in FIG. 16C, the target layer TL is patterned using the patterned photoresist layer as an etching mask. In some embodiments, the patterning the target layer includes applying an etching process to the target layer using the patterned photoresist layer as an etching mask. The portions of the target layer exposed within the openings of the patterned photoresist layer are etched while the remaining portions are protected from etching. Further, the patterned photoresist layer may be removed by wet stripping or plasma ashing, as shown in FIG. 16D.

In some embodiments, two hard mask layers 30, 32 are used to pattern the absorber layer 25. The use of two thinner hard mask layers as opposed to a single thicker hard mask layer provides improved control of the pattern profile of the etched patterns when using chromium-based absorber layers. Cr-based absorber layers, such as CrN or nitrogen rich CrON or CrCON layer have a higher EUV absorption coefficient than other absorber layers. The higher EUV absorption coefficient enables the use of reduced thickness absorber layers, which in turn suppresses three-dimensional effects in the EUV lithography.

The cyclical etching operation of the absorber layer disclosed herein provides a reduction in the thickness of the etching byproduct sidewall 65 on the openings 42 in the absorber layer 25. In some embodiments, the etching byproduct sidewall is reduced by about 40% to about 66% compared to absorber etching operations that do not include the cyclical etching operation disclosed herein. In other embodiments, the etching byproduct sidewall is reduced by about 45% to about 55%. In some embodiments, the footing angle α of the etching product sidewall is increased to over 75°, and to over 88° in other embodiments. In some embodiments, the footing angle α ranges from about 77° to about 90°. In some embodiments, the cyclical etching operation of the absorber layer disclosed herein provides improved resolution of the circuit pattern 42 formed in absorber layer 25. Embodiments of the disclosure provide improved mask critical dimension (CD) uniformity, and prevent mask induced CD and profile decay. Embodiments of the disclosure also prevent undercutting as a result of the absorber layer etching operation. Embodiments of the disclosure are performed in the same etching tools currently used to etch the absorber layer. Thus, no new tooling is required to practice the disclosed methods.

It will be understood that not all advantages have been necessarily discussed herein, no particular advantage is required for all embodiments or examples, and other embodiments or examples may offer different advantages.

According to an embodiment of the disclosure, a method of manufacturing a photomask includes forming a reflective multilayer stack over a substrate and forming a capping layer over the reflective multilayer stack. An absorber layer is formed over the capping layer and a hard mask is formed over the absorber layer. An opening is formed in the hard mask exposing the absorber layer. The absorber layer is etched using the hard mask as an etching mask. The etching the absorber layer includes in order: applying a first etching gas to the absorber layer, turning on a bias power and a source power, turning off the bias power and the source power, applying a second etching gas to the absorber layer, wherein the first etching gas and the second etching gas are different, and turning on the source power without turning on the bias power. In an embodiment, forming the reflective multilayer stack includes forming a plurality of alternating molybdenum and silicon layers. In an embodiment, the reflective multilayer stack comprises 20 to 60 pairs of molybdenum and silicon layers. In an embodiment, the capping layer includes ruthenium. In an embodiment, the first etching gas includes oxygen. In an embodiment, the second etching gas includes chlorine. In an embodiment, the second etching gas includes C_{X}H_{Y}F_{Z}, where 0≤x≤10, 0≤y≤12, and 0≤z≤12, and only one of x, y, and z can be 0 for a given second etching gas. In an embodiment, a mixture of the first etching gas and the second etching gas is applied during the applying the second etching gas to the absorber layer. In an embodiment, the method includes forming an anti-reflection layer over the capping layer before forming the absorber layer. In an embodiment, the anti-reflection layer includes a tantalum compound.

According to another embodiment of the disclosure, a method of manufacturing a reflective photomask includes forming a hard mask layer over a reflective photomask blank. The reflective photomask blank includes: a reflective multilayer stack disposed over a substrate, a capping layer disposed over the reflective multilayer stack, and an absorber layer disposed over the capping layer. The hard mask layer is patterned to form an opening in the hard mask layer. The absorber layer is etched in a chamber using the patterned hard mask layer as an etching mask. The etching the absorber layer includes operations of: a) introducing an oxygen-containing gas into the chamber, b) turning on a bias power and a source power for a first period of time, c) turning off the bias power and the source power, d) introducing a fluorocarbon gas into the chamber, and e) turning on the source power for a second period of time and not turning on the bias power during the second period of time. In an embodiment, the fluorocarbon gas is represented as C_{X}H_{Y}F_{Z}, where 0<x≤10, 0≤y≤12, and 0<z≤12. In an embodiment, the method includes repeating operations a) to e). In an embodiment, the absorber layer includes chromium. In an embodiment, the hard mask layer includes a tantalum compound.

Another embodiment of the disclosure is a method of manufacturing a photomask including forming a hard mask layer including a first tantalum compound over a photomask blank. The photomask blank includes: a reflective multilayer stack disposed over a substrate, a capping layer disposed over the reflective multilayer stack, an intermediate layer including a second tantalum compound disposed over the capping layer; and an absorber layer disposed over the intermediate layer. The hard mask layer is photolithographically patterned to expose a portion of the absorber layer, and the absorber layer is etched in a chamber using the patterned hard mask layer as an etching mask to form an opening in the absorber layer. Etching the absorber layer includes operations of: a) introducing an oxygen-containing gas into the chamber, b) turning on a bias power and a source power for a first period of time, c) turning off the bias power and the source power, d) introducing a fluorocarbon gas into the chamber, e) turning on the source power for a second period of time and not turning on the bias power during the second period of time, and f) forming a sidewall layer comprising a reaction product of the oxygen-containing gas, the fluorocarbon gas, and the absorber layer on sidewalls of the opening. In an embodiment, the method includes repeating operations a), b), c), d), and e). In an embodiment, the method includes performing an over etch operation using an over etch gas. In an embodiment, the over etch gas includes a mixture of oxygen and chlorine. In an embodiment, the sidewall layer includes a layer of CrOₓF_{y} or CrOₓCl_{y}, where 0<x≤10, and 0<y≤10.

Another embodiment of the disclosure is a method of manufacturing a semiconductor device, including forming a hard mask layer over a photomask blank. The photomask blank includes: a reflective multilayer stack disposed over a substrate, a capping layer disposed over the reflective multilayer stack, and an absorber layer disposed over the capping layer. An opening in the hard mask layer is formed exposing the absorber layer. The absorber layer is etched using the hard mask layer as an etching mask to form a patterned photomask. The etching the absorber layer includes: introducing a first etching gas into a chamber containing the photomask blank, turning on a bias power and a source power for a first time period, turning off the bias power and the source power after the first time period, introducing a second etching gas into the chamber after turning off the bias power and source power, wherein the first etching gas and the second etching gas are different, and turning on the source power without turning on the bias power for a second period of time after introducing the second etching gas. The patterned photomask is used to form a pattern in a photoresist layer disposed over a semiconductor substrate. In an embodiment, the using the patterned photomask to form a pattern in a photoresist layer includes: directing actinic radiation toward the patterned photomask such that the actinic is reflected off the patterned photomask and the reflected actinic radiation is directed towards the photoresist layer to form a latent pattern in the photoresist layer, and developing the latent pattern to form a pattern in the photoresist layer. In an embodiment, the actinic radiation is extreme ultraviolet radiation. In an embodiment, the reflective multilayer stack includes 20 to 60 pairs of molybdenum and silicon layers. In an embodiment, the capping layer includes ruthenium. In an embodiment, the first etching gas includes oxygen. In an embodiment, the second etching gas includes chlorine. In an embodiment, the second etching gas includes C_{X}H_{Y}F_{Z}, where 0<x≤10, 0≤y≤12, and 0<z≤12. In an embodiment, the photomask blank includes an intermediate layer including a tantalum compound disposed between the capping layer and the absorber layer.

Another embodiment of the disclosure is a method of manufacturing a semiconductor device including directing actinic radiation from an actinic radiation source to a reflective photomask. The reflective photomask includes: a reflective multilayer stack disposed over a substrate, a capping layer disposed over the reflective multilayer stack, a patterned absorber layer including at least one pattern feature disposed over the capping layer, and a sidewall layer disposed over sidewalls of the at least one pattern feature, wherein the sidewalls include a layer of CrOₓF_{y} or CrOₓCl_{y}, where 0<x≤10, and 0<y≤10. Patterned actinic radiation reflected from the reflective photomask is directed towards a semiconductor substrate coated with a photoresist layer to form a latent image in the photoresist layer. A developer is applied to the photoresist layer to develop the latent image and form a pattern in the photoresist layer. In an embodiment, the patterned absorber layer includes chromium. In an embodiment,

the actinic radiation is extreme ultraviolet radiation. In an embodiment, the reflective multilayer stack includes 20 to 60 pairs of molybdenum and silicon layers. In an embodiment, the capping layer includes ruthenium.

Another embodiment of the disclosure is a reflective photomask including a reflective multilayer stack disposed over a substrate and a capping layer disposed over the reflective multilayer stack. A patterned absorber layer including at least one pattern feature is disposed over the capping layer and a sidewall layer is disposed over sidewalls of the at least one pattern feature. The sidewall layer includes a layer of CrOₓF_{y} or CrOₓCl_{y}, where 0<x≤10, and 0<y≤10. In an embodiment, the reflective multilayer stack includes 20 to 60 pairs of molybdenum and silicon layers. In an embodiment, the capping layer includes ruthenium. In an embodiment, the absorber layer includes chromium. In an embodiment, the absorber layer includes chromium nitride. In an embodiment, the reflective photomask includes an intermediate layer disposed between the capping layer and the absorber layer. In an embodiment, the intermediate layer is anti-reflective layer. In an embodiment, the intermediate layer is made of a tantalum compound. In an embodiment, a thickness of the sidewall layer ranges from 0.5 nm to 5 nm. In an embodiment, the thickness of the sidewall layer ranges from 1 nm to 3 nm.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a photomask, comprising:
forming a reflective multilayer stack over a substrate;
forming a capping layer over the reflective multilayer stack;
forming an absorber layer over the capping layer;
forming a hard mask over the absorber layer;
forming an opening in the hard mask exposing the absorber layer; and
etching the absorber layer using the hard mask as an etching mask,
wherein the etching the absorber layer comprises in order:
applying a first etching gas to the absorber layer;
turning on a bias power and a source power;
turning off the bias power and the source power;
applying a second etching gas to the absorber layer,
wherein the first etching gas and the second etching gas are different; and
turning on the source power without turning on the bias power.

2. The method according to claim 1, wherein forming the reflective multilayer stack comprises forming a plurality of alternating molybdenum and silicon layers.

3. The method according to claim 2, wherein the reflective multilayer stack comprises 20 to 60 pairs of molybdenum and silicon layers.

4. The method according to claim 1, wherein the capping layer comprises ruthenium.

5. The method according to claim 1, wherein the first etching gas comprises oxygen.

6. The method according to claim 1, wherein the second etching gas comprises chlorine.

7. The method according to claim 1, wherein the second etching gas comprises C_{X}H_{Y}F_{Z}, where 0≤X≤10, 0≤Y≤12, and 0≤Z≤12, and only one of x, y, and z can be 0 for a given second etching gas.

8. The method according to claim 1, wherein a mixture of the first etching gas and the second etching gas is applied during the applying the second etching gas to the absorber layer.

9. The method according to claim 1, further comprising forming an anti-reflection layer over the capping layer before forming the absorber layer.

10. The method according to claim 9, wherein the anti-reflection layer comprises a tantalum compound.

11. A method of manufacturing a reflective photomask, comprising:
forming a hard mask layer over a reflective photomask blank,
wherein the reflective photomask blank comprises:
a reflective multilayer stack disposed over a substrate;
a capping layer disposed over the reflective multilayer stack; and
an absorber layer disposed over the capping layer;
patterning the hard mask layer to form an opening in the hard mask layer; and
etching the absorber layer in a chamber using the patterned hard mask layer as an etching mask,
wherein the etching the absorber layer comprises operations of:
a) introducing an oxygen-containing gas into the chamber;
b) turning on a bias power and a source power for a first period of time;
c) turning off the bias power and the source power;
d) introducing a fluorocarbon gas into the chamber; and
e) turning on the source power for a second period of time and not turning on the bias power during the second period of time.

12. The method according to claim 11, wherein the fluorocarbon gas is represented as C_{X}H_{Y}F_{Z}, where 0<X≤10, 0≤Y≤12, and 0<Z≤12.

13. The method according to claim 11, further comprising repeating operations a) to e).

14. The method according to claim 11, wherein the absorber layer comprises chromium.

15. The method according to claim 11, wherein the hard mask layer comprises a tantalum compound.

16. A reflective photomask, comprising:
a reflective multilayer stack disposed over a substrate;
a capping layer disposed over the reflective multilayer stack;
a patterned absorber layer comprising at least one pattern feature disposed over the capping layer; and
a sidewall layer disposed over sidewalls of the at least one pattern feature,
wherein the sidewall layer comprises a layer of CrOₓF_{y} or CrOₓCl_{y}, where 0<x≤10, and 0<y≤10.

17. The reflective photomask of claim 16, wherein the reflective multilayer stack comprises 20 to 60 pairs of molybdenum and silicon layers.

18. The reflective photomask of claim 16, wherein the capping layer comprises ruthenium.

19. The reflective photomask of claim 16, wherein the absorber layer comprises chromium.

20. The reflective photomask of claim 16, wherein the absorber layer comprises chromium nitride.
